(19) United States
(12) Patent Application Publication
(10) Pub. No.: US 2024/0112928 A1
(43) Pub. Date: Apr. 4, 2024

(54) TRIMMING METHOD

(71) Applicant: Taiwan Semiconductor Manufacturing Company, Ltd., Hsinchu (TW)

(72) Inventors: An-Hsuan Lee, Hsinchu (TW); Chen-Hao Wu, Hsinchu (TW); Chun-Hung Liao, Taichung (TW); Huang-Lin Chao, Hillsboro, OR (US)

(73) Assignee: Taiwan Semiconductor Manufacturing Company, Ltd., Hsinchu (TW)

(21) Appl. No.: 18/152,715

(22) Filed: Jan. 10, 2023

Related U.S. Application Data
(60) Provisional application No. 63/412,554, filed on Oct. 3, 2022.

(51) Int. Cl. H01L 21/67; H01L 21/02; H01L 21/304

(52) U.S. Cl. CPC H01L 21/67092; H01L 21/02013; H01L 21/02021; H01L 21/304; H01L 2221/68327

(57) ABSTRACT

A trimming method is provided. The trimming method includes the following steps. A first wafer including a substrate and a device layer over a first side of the substrate is provided. The first wafer is bonded to a second wafer with the first side of the substrate facing toward the second wafer. An edge trimming process is performed to remove a trimmed portion of the substrate from a second side opposite to the first side vertically downward toward the first side in a first direction along a perimeter of the substrate, wherein the edge trimming process results in the substrate having a flange pattern laterally protruding from the device layer and laterally surrounding an untrimmed portion of the substrate along a second direction perpendicular to the first direction. A grinding process is performed on the untrimmed portion of the substrate from the second side to thin the untrimmed portion of the substrate to a reduced thickness in the first direction, wherein the grinding process results in the reduced thickness being greater than a thickness of the flange pattern.

### CROSS-REFERENCE TO RELATED APPLICATION

This application claims the priority benefit of U.S. provisional application Ser. No. 63/412,554, filed on Oct. 3, 2022. The entirety of the above-mentioned patent application is hereby incorporated by reference herein and made a part of this specification.

### BACKGROUND

In recent years, owing to the need in miniaturizing the semiconductor chips, the requirements of wafer thinning process become more severe in semiconductor manufacturing process. Generally, during the wafer thinning process, the grinding process performed on the backside of the semiconductor wafer may cause the wafer edge to be damaged. Subsequently, an edge trimming process may be performed to remove the outer edge of the wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A through FIG. 1E illustrate schematic cross-sectional views of various stages of a trimming method of a stacked wafer structure, in accordance with some embodiments of the present disclosure.

FIG. 2 illustrates a schematic top view of some embodiments of the stage of FIG. 1A in the trimming method of a stacked wafer structure.

FIG. 3A through FIG. 3B illustrates schematic cross-sectional views of various stages of a trimming method of a stacked wafer structure, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

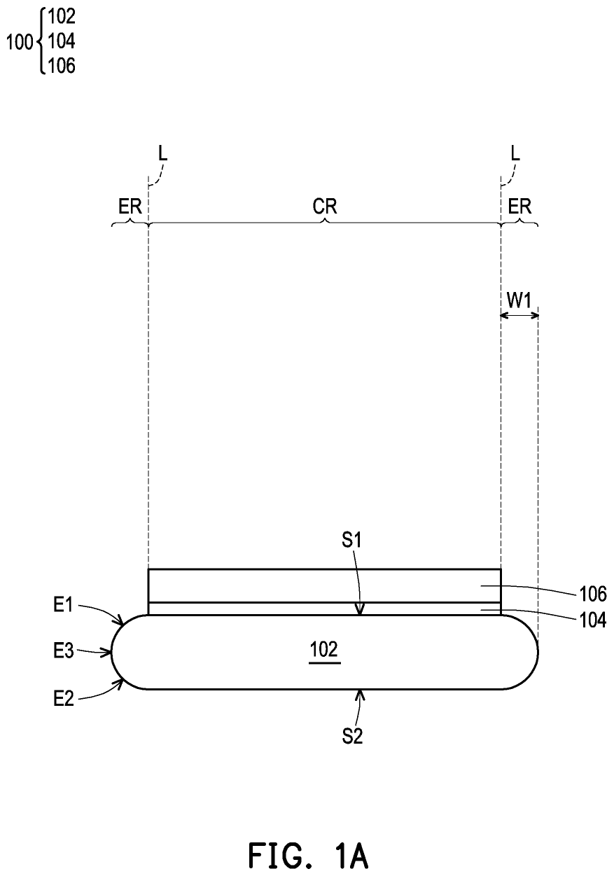

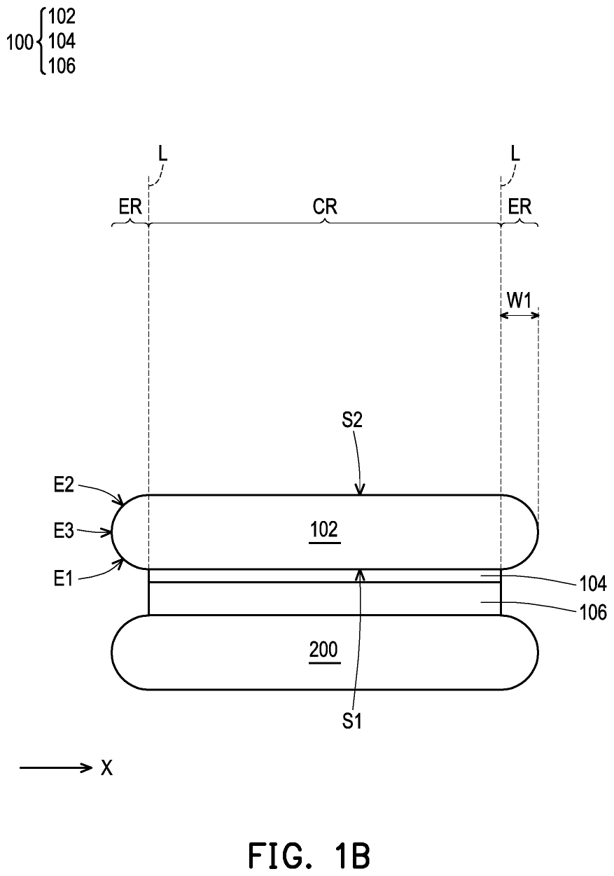

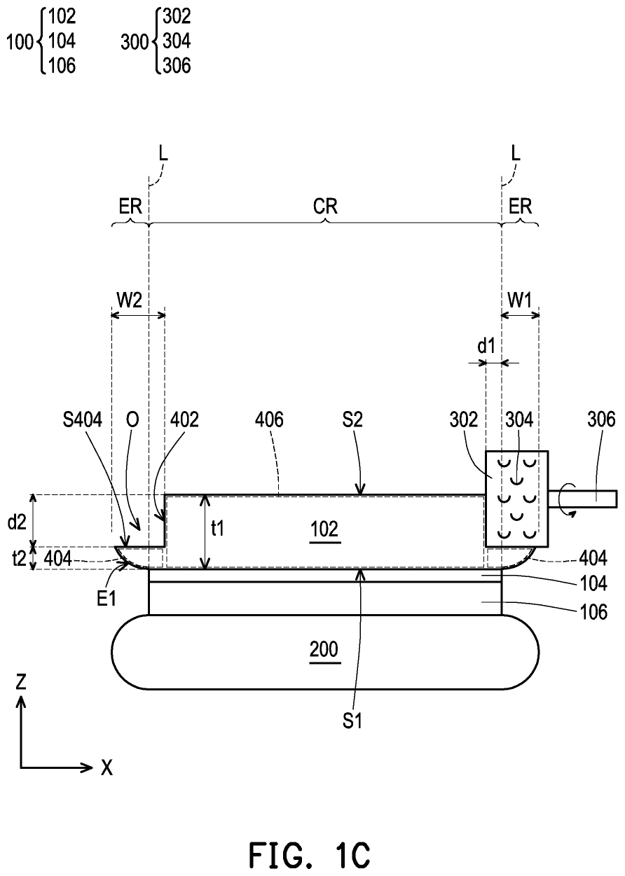

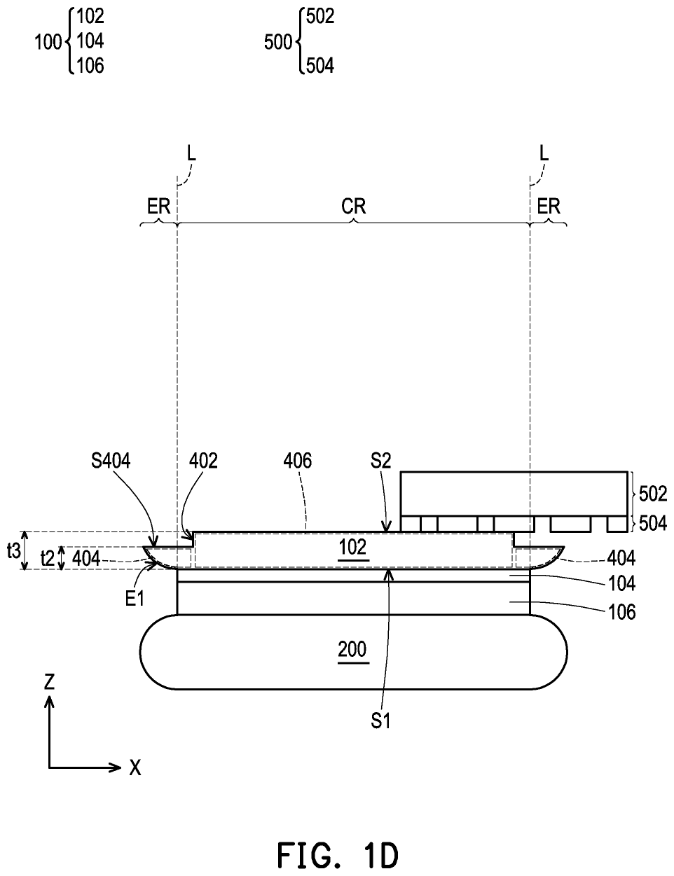

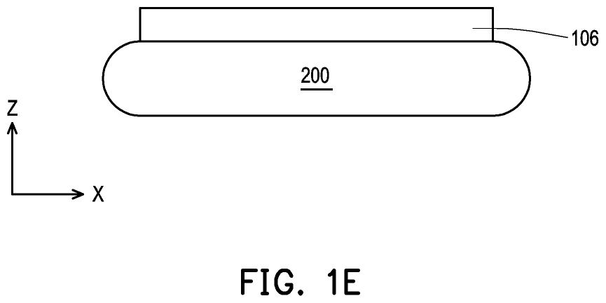

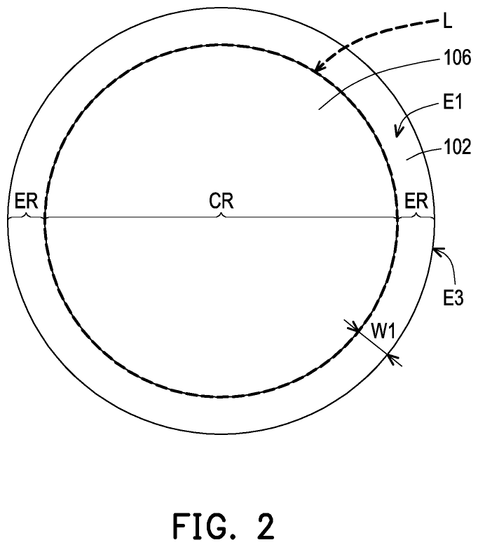

FIG. 1A through FIG. 1E illustrate schematic cross-sectional views of various stages of a trimming method of a stacked wafer structure, in accordance with some embodiments of the present disclosure. FIG. 2 illustrates a schematic top view of some embodiments of the stage of FIG. 1A in the trimming method of a stacked wafer structure. Referring to FIG. 1A, a first wafer 100 is provided. The first wafer 100 may be of any appropriate size and shape. In some embodiments, the first wafer 100 is a substantially circular wafer. In some embodiments, the first wafer 100 may be a semiconductor wafer such as a silicon bulk wafer or a gallium arsenide wafer. In some embodiments, the first wafer 100 may include, for example, silicon, strained silicon, silicon alloy, silicon carbide, silicon-germanium, silicon-germanium carbide, germanium, a germanium alloy, germanium-arsenic, indium-arsenic, group III-V semiconductors.

In some embodiments, as shown in FIG. 1A, the first wafer 100 includes a semiconductor substrate 102, an etch stop layer 104 and a device layer 106. As such, in some embodiments, the first wafer 100 is a device wafer. Further, as shown in FIG. 2, the first wafer 100 is a round-shaped wafer. In some embodiments, the semiconductor substrate 102 is a silicon substrate. Alternatively, the semiconductor substrate 102 may be formed of other semiconductor materials such as silicon alloy, silicon carbide, silicon-germanium, silicon-germanium, silicon-germanium carbide, germanium, a germanium alloy, germanium-arsenic, indium-arsenic, III-V compound semiconductor materials, and the like.

In some embodiments, the semiconductor substrate 102 has a central region CR and an edge region ER surrounding the central region CR. Since the first wafer 100 is a round-shaped wafer, as shown in FIG. 2, the edge region ER may be referred to as a circumferential edge region. As shown in FIG. 1A and FIG. 2, the edge region ER has an inner defining line L, which is also the interface between the edge region ER and the central region CR. Further, as shown in FIG. 2, from the top view, the edge region ER is in a shape of a closed-loop ring along a perimeter of the semiconductor substrate 102. In some embodiments, as shown in FIG. 1A, the semiconductor substrate 102 includes a first surface S1 and a second surface S2 opposite to the first surface S1 in the central region CR. For example, a side where the first surface S1 is located may be referred to the front side of the semiconductor substrate 102, and the opposite side where the second surface S2 is located may be referred to the backside of the semiconductor substrate 102. In some embodiments, the outermost extent of each of the first surface S1 and the second surface S2 is circumferentially bounded by an edge region ER. In some embodiments, as shown in FIG. 1A, the edge region ER includes a first bevel region E1 extending between the first surface S1 and an outermost edge E3 of the edge region ER, and a second bevel region E2 extending between the outermost edge E3 of the edge region ER and the second surface S2. In some instances, the first bevel region E1 and the second bevel region E2 have the same radius of curvature. The first bevel region E1 and the second bevel region E2 in FIG. 1A is illustrated as with curve shaped or a rounded edge. In other embodiments, the semiconductor substrate 102 may have a chamfered edge or a beveled edge. In some embodiments, the width W1 of the edge region ER is measured from the inner defining line L to the outermost edge E3 of the edge region ER (or the semiconductor substrate 102). It is appreciated that the dimensions recited throughout the description are merely examples, and may be changed to different values.

In some embodiments, the etch stop layer 104 is formed on the first surface S1 of the semiconductor substrate 102. In detail, as shown in FIG. 1A, the etch stop layer 104 is formed within the central region CR of the semiconductor substrate 102. It is designed that there is high removing (e.g., etching) selectivity among the material of the semiconductor substrate 102 and the material of the etch stop layer 104, so that one of the semiconductor substrate 102 and the etch stop layer 104 can be removed without significantly removing the other one.

Continued referring to FIG. 1A, the device layer 106 is formed on the etch stop layer 104. In detail, as shown in FIG. 1A, the device layer 106 is formed within the central region CR of the semiconductor substrate 102. In some embodiments, the device layer 106 may include a plurality of devices (not shown), and/or an interconnect structure (not shown). The devices may be, for example, transistor devices, light sensing devices or image sensors. In certain embodiments, the devices may include, for example, photo diodes (PD), photo transistors, or a combination thereof. In certain embodiments, the devices may include, for example, CMOS image sensors (CIS) or charge-coupled device (CCD) sensors. In some embodiments, additional semiconductor devices or electrical components with different functions or integrated circuits may also be included in the device layer 106. In some embodiments, the interconnect structure may be formed over the semiconductor substrate 102 and be electrically coupled with the devices and/or other electrical components in the device layer 106. The scope of the disclosure is not limited to the embodiments or drawings described therein.

Referring to FIG. 1B, a first wafer 100 is bonded to a second wafer 200. For example, the second wafer 200 is a semiconductor wafer and functions as a carrier wafer herein. In some embodiments, the second wafer 200 may include, for example, silicon, strained silicon, silicon alloy, silicon carbide, silicon-germanium, silicon-germanium carbide, germanium, a germanium alloy, germanium-arsenic, indium-arsenic, group III-V semiconductors. In some embodiments, the second wafer 200 includes glass or ceramic materials. In some embodiments, as shown in FIG. 1B, after the first wafer 100 and the second wafer 200 are bonded to each other, the device layer 106 of the first wafer 100 is in contact with the second wafer 200. That is, after the bonding process of the first wafer 100 and the second wafer 200, the device layer 106 is nearer the second wafer 200 than the semiconductor substrate 102. In other words, the central region CR where the device layer 106 disposed in may be referred to as a bonging region, and the edge region ER laterally protruding from the side surface of the device layer 106 along a direction X may be referred to as a non-bonging region. In some embodiments, when bonding the first wafer 100 and the second wafer 200, the molecular bonding technique may be employed. For example, bringing the device layer 106 of the first wafer 100 and the second wafer 200 into directly contact, and the first wafer 100 and the second wafer 200 are bonded through Van der Waals force without using a specific bonding material or an adhesive. However, the disclosure is not limited thereto. In some alternative embodiments, the bonding process of the first wafer 100 and the second wafer 200 includes forming a dielectric layer (e.g., oxide layer) (not shown) on the second wafer 200, performing plasma activation steps on the dielectric layer (e.g., oxide layer) on the second wafer 200 and a dielectric layer in the device layer 106 of the first wafer 100, and then bonding the second wafer 200 and the first wafer 100 together through a dielectric-to-dielectric bonding (e.g., an oxide-to-oxide bonding). In some alternative embodiments, when bonding the first wafer 100 and the second wafer 200, the hybrid bonding technique may be employed. During the bonding process, a pressure may be applied to force the first wafer 100 and the second wafer 200 against each other. The temperature of the first wafer 100 and/or the second wafer 200 may also be increased in the bonding process.

In some embodiments, the top-view shape of the second wafer 200 may be substantially the same as the top-view shape of the first wafer 100, which may have a circular top view shape, as shown in FIG. 2. Further, the top-view size of the second wafer 200 may also be substantially equal to the top-view size of the first wafer 100. In some embodiments, the first wafer 100 and the second wafer 200 have the same diameter. That is to say, the semiconductor substrate 102 of the first wafer 100 has the same diameter as the second wafer 200. In other embodiments, the first wafer 100 and the second wafer 200 may have different diameters. The dimensions of the first wafer 100 and the second wafer 200 may depend on the design requirement and construe no limitation in the disclosure.

Referring to FIG. 1C, an edge trimming process is then performed. In some embodiments, as shown in FIG. 1C, the edge trimming process is performed by bringing a trimming tool 300 into contact with the semiconductor substrate 102 of the first wafer 100 along the perimeter of the semiconductor substrate 102. In some embodiments, the trimming tool 300 includes a scribing wheel or a trimming blade wheel. As shown in FIG. 1C, the trimming tool 300 has abrasive elements 304 (e.g., diamond particles) bonded to a core 302, and the core 302 is configured to rotate around an axis 306, as the abrasive elements 304 are brought into contact with the semiconductor substrate 102 of the first wafer 100. In some embodiments, the core 302 is a blade wheel having a circular cross-section along a thickness direction Z perpendicular to the direction X. However, the scope of the disclosure is not limited to the embodiments or drawings described therein, the edge trimming process may be performed through any other suitable tools capable of cutting away the material of the semiconductor substrate 102. For example, the edge trimming process is performed by laser heating.

As shown in FIG. 1B and FIG. 1C, the edge trimming process is performed to cut or trim off a portion of the semiconductor substrate 102 of the first wafer 100 from the second surface S2 and the second bevel region E2 vertically downward along the thickness direction Z (i.e., towards the first surface S1 and the first bevel region E1) to form a trimmed edge 402, a flange pattern 404 and a body pattern 406. In detail, the edge trimming process is performed to cut the semiconductor substrate 102 from the second surface S2 and the second bevel region E2 vertically downward towards the first surface S1 and the first bevel region E1 but not cutting through. As shown in FIG. 1C, a portion of the first bevel region E1 still remains after the edge trimming process.

Further, as shown in FIG. 1C, the trimmed edge 402 is located within the central region CR of the semiconductor substrate 102. That is to say, along the thickness direction Z, a projection location of the trimmed edge 402 onto the second wafer 200 is within a span of a vertical projection of the device layer 106 onto the second wafer 200. In some embodiments, a distance d1 along the direction X between the trimmed edge 402 and the inner defining line L of the edge region ER is larger than about 10 um. However, the disclosure is not limited thereto. In some alternative embodiments, the trimmed edge 402 is aligned to the inner defining line L of the edge region, and thus no distance along the direction X is between the trimmed edge 402 and the inner defining line L.

From another point of view, referring to both FIG. 1B and FIG. 1C, during the edge trimming process, a portion of the semiconductor substrate 102 in the central region CR and a portion of the semiconductor substrate 102 in the edge region ER are removed to form an opening O in both the central region CR and the edge region ER of the semiconductor substrate 102. That is, in the edge trimming process, both the central region CR and the edge region ER are trimmed. In such case, the trimming width W2, which is measured from the trimmed edge 402 to a reference plane extending from the outermost edge E3, of the edge trimming process is greater than the width W1 of the edge region ER. In some embodiments, the trimming width W2 ranges from about 0.3 mm to about 3 mm. However, the disclosure is not limited thereto. In embodiments where the trimmed edge 402 is aligned to the inner defining line L, the trimming width W2 of the edge trimming process is substantially equal to the width W1 of the edge region ER. It is noted that since the edge trimming process is performed not to cut through the semiconductor substrate 102, a portion of the semiconductor substrate 102 in the central region CR can also be trimmed to ensure the wanted trimmed portion in the edge region ER to be removed completely without damaging device layer 106 of the first wafer 100. Thereby, after the edge trimming process, the edge shape of the device layer 106 can be preserved. Referring to both FIG. 2 and FIG. 1C, since the edge trimming process is performed along the perimeter of the semiconductor substrate 102, the opening O may be referred to as a ring-shaped opening. That is, the trimmed portion of the semiconductor substrate 102 is in a shape of a closed-loop ring.

In some embodiments, as shown in FIG. 1C, the flange pattern 404 is located right under the ring-shaped opening O, and the body pattern 406 is laterally surrounded by the ring-shaped opening O and the flange pattern 40. That is to say, the flange pattern 404 is constituted by a portion of the semiconductor substrate 102 in the central region CR and a portion of the semiconductor substrate 102 in the edge region ER, and the body pattern 406 is constituted by another portion of the semiconductor substrate 102 in the central region CR. In other words, the body pattern 406 is disposed in the central region CR, while a portion of the flange pattern 404 is in the central region CR, and another portion of the flange pattern 404 is in the edge region ER. And, the portion of the flange pattern 404 in the edge region ER protrudes from the side surface of the device layer 106 along the direction X. In some embodiments, as shown in FIG. 1C, the trimmed edge 402 is defined by the body pattern 406. That is, the body pattern 406 is the untrimmed portion of the semiconductor substrate 102 in the central region CR. As such, the second surface S2 and the first surface S1 both are surfaces of the body pattern 406. Further, in some embodiments, as shown in FIG. 1C, the sidewall of the ring-shaped opening O is the trimmed edge 402 defined by the body pattern 406, and a bottom surface of the ring-shaped opening O is defined by the flange pattern 404. Since the flange pattern 404 is located right under the ring-shaped opening O, the bottom surface of the ring-shaped opening O is the surface S404 (illustrated as the top surface in FIG. 1C) of the flange pattern 404.

As shown in FIG. 1C, since the ring-shaped opening O does not penetrate through the semiconductor substrate 102 of the first wafer 100, along the thickness direction Z, the depth d2 of the ring-shaped opening O (i.e., the trimming depth, or the thickness of the trimmed portion) is less than the thickness t1 of the semiconductor substrate 102. In some embodiments, the thickness t1 of the semiconductor substrate 102 is measured from the first surface S1 to the second surface S2. As such, the thickness of the body pattern 406 is the thickness t1. Further, in some embodiments, the depth d2 of the ring-shaped opening O (i.e., the trimming depth, or the thickness of the trimmed portion) is measured from the surface S404 of the flange pattern 404 (i.e., bottom surface of the ring-shaped opening O) to a reference plane extending from the second surface S2, and the thickness t2 of the flange pattern 404 is measured from the surface S404 of the flange pattern 404 to a reference plane extending from the first surface S1. As such, the thickness t1 of the semiconductor substrate 102 is the addition of the depth d2 of the ring-shaped opening O and the thickness t2 of the flange pattern 404, and then during the edge trimming process, the depth d2 of the ring-shaped opening O is decided by the thickness t2 of the flange pattern 404. In certain embodiments, the depth d2 of the ring-shaped opening O (i.e., the trimming depth, or the thickness of the trimmed portion) is greater than 0 μm to less than about 775 μm. In certain embodiments, the thickness t2 of the flange pattern 404 is in a range of between greater than 0 μm and about 150 μm.

In some embodiments, as shown in FIG. 1C, the trimmed edge 402 is substantially perpendicular to the second surface S2. However, the disclosure is not limited thereto. In some alternative embodiments, the trimmed edge 402 is slant to the second surface S2. In some embodiments, as shown in FIG. 1C, the trimmed edge 402 and the surface S404 meet at a point. However, the disclosure is not limited thereto. In some alternative embodiments, the trimmed edge 402 is connected with the surface S404 through a rounded corner.

Referring to FIG. 1D, a grinding process is performed on the semiconductor substrate 102 of the first wafer 100 to thin down the semiconductor substrate 102. That is, the grinding process is performed to reduce the thickness of the semiconductor substrate 102. In detail, as shown in FIG. 1C and FIG. 1D, since the level height of the surface S404 of the flange pattern 404 is lower than the level height of the second surface S2 of the body pattern 406, during the grinding process, the body pattern 406 is thinned until the remained portion of the body pattern 406 has a desired thickness t3. In some embodiments, the desired reduced thickness t3 of the body pattern 406 is greater than the thickness t2 of the flange pattern 404. That is, after the grinding process, the level height of the surface S404 of the flange pattern 404 is still lower than the level height of the second surface S2 of the body pattern 406. In other words, during the grinding process, the semiconductor substrate 102 in the edge region ER (i.e., non-bonding region) would not be ground. In certain embodiments, the reduced thickness t3 of the body pattern 406 (or the semiconductor substrate 102) is in a range of between about 5 μm and about 100 μm. In some embodiments, the thickness difference between the thickness t3 of the body pattern 406 and the thickness t2 of the flange pattern 404 should be greater than 1 μm. In certain embodiments, the thickness difference between the thickness t3 of the body pattern 406 and the thickness t2 of the flange pattern 404 is at least 2 μm. As such, during the grinding process, the level height of the surface S404 of the flange pattern 404 can be ensured to be lower than the level height of the second surface S2 of the body pattern 406, even with the edge trimming process error and the grinding process error. From another point of view, as shown in FIG. 1C and FIG. 1D, the body pattern 406 and the flange pattern 404 collectively define a staircase shaped structure. That is to say, during the edge trimming process and during the grinding process, the semiconductor substrate 102 is rendered to have a stepped profile.

It is noted that since before performing the grinding process, the semiconductor substrate 102 in the edge region ER (i.e., non-bonding region) is trimmed from the second bevel region E2 to form the flange pattern 404 with the surface S404 at the level height lower than the level height of the second surface S2 of the body pattern 406 during the grinding process, an edge-cracking issue arise from the semiconductor substrate 102 in edge region ER (i.e., non-bonding region) due to unable to resist the stress from the grinding process can be eliminated. Therefore, no peeling will happen during the grinding process. Further, it is noted that since during the grinding process, the semiconductor substrate 102 in the edge region ER (i.e., non-bonding region) would not be ground and contact in, no sealant is needed to support the semiconductor substrate 102 in the edge region ER (i.e., non-bonding region) during the grinding process. Further, it is noted that during the grinding process, the flange pattern 404 with a portion in the edge region ER extending over the second wafer 200 along the direction X can protect the underlying second wafer 200 from being damage.

In some embodiments, the grinding process may comprise bringing a grinding wheel 500 into contact with the second surface S2 of the body pattern 406 (or the semiconductor substrate 102), as shown in FIG. 1D. In some embodiments, as shown in FIG. 1D, the grinding wheel 500 may comprise a plurality of abrasive elements 504 disposed onto a base 502. In some embodiments, the base 502 may comprise a ring-shaped structure as viewed from a top of the base 502. Further, in some embodiments, the grinding process may comprise a coarse grinding process configured to achieves a surface roughness (Ra, roughness average) ranging from about 5 Å to about 25 Å.

Referring to FIG. 1E, the semiconductor substrate 102 (including the flange pattern 404 and the body pattern 406) and the etch stop layer 104 are removed, such that the trimming method of the stacked wafer structure is substantially completed. In some embodiments, the semiconductor substrate 102 including the flange pattern 404 and the body pattern 406 is removed by performing a dry etching process and a wet etching process. In certain embodiments, the dry etching process is performed before performing the wet etching process. However, the disclosure is not limited thereto. In some alternative embodiments, the dry etching process is performed after performing the wet etching process. In some embodiments, the dry etching process performed to remove the semiconductor substrate 102 includes a reactive ion etching (RIE) process or other suitable processes. In certain embodiments, the wet etching process performed to remove the semiconductor substrate 102 employs hydrofluoric acid/nitric acid/acetic acid (HNA) as the etchant. As mentioned above, there is high removing (e.g., etching) selectivity among the material of the semiconductor substrate 102 and the material of the etch stop layer 104, and thus during the removal process for the semiconductor substrate 102, this removal process is stopped at the etch stop layer 120. As such, the etch stop layer 120 is used to prevent the underlying device layer 106 from damage caused by the over-etching of the semiconductor substrate 102. Further, in some embodiments, the etch stop layer 104 is removed by performing a wet etching process. It is noted that during the edge trimming process, the semiconductor substrate 102 is not trimmed through the first bevel region E1 and the flange pattern 404 remains over the device layer, and thus after the removal processes of the semiconductor substrate 102, the device layer 106 with the preserved and unchanged edge is disposed on the second wafer 200. Thereby, the keep out zone (KOZ) near the edge of the device layer 106 can be accordingly reduced.

In the trimming method of the stacked wafer structure shown in FIG. 1A to FIG. 1E, before the grinding process, the flange pattern 404 (or the ring-shaped opening O) is formed by the edge trimming process. However, the disclosure is not limited thereto. In some alternative embodiments, the flange pattern 404 (or the ring-shaped opening O) is formed by performing the edge trimming process followed by an etching or bevel etching process. In some embodiments, the bevel etching process includes a wet bevel etching process, a plasma bevel process, or laser heating. It is noted that by using the combination of the edge trimming process and the bevel etching process to form the flange pattern, the higher accuracy on the control of the trimming depth can be achieved.

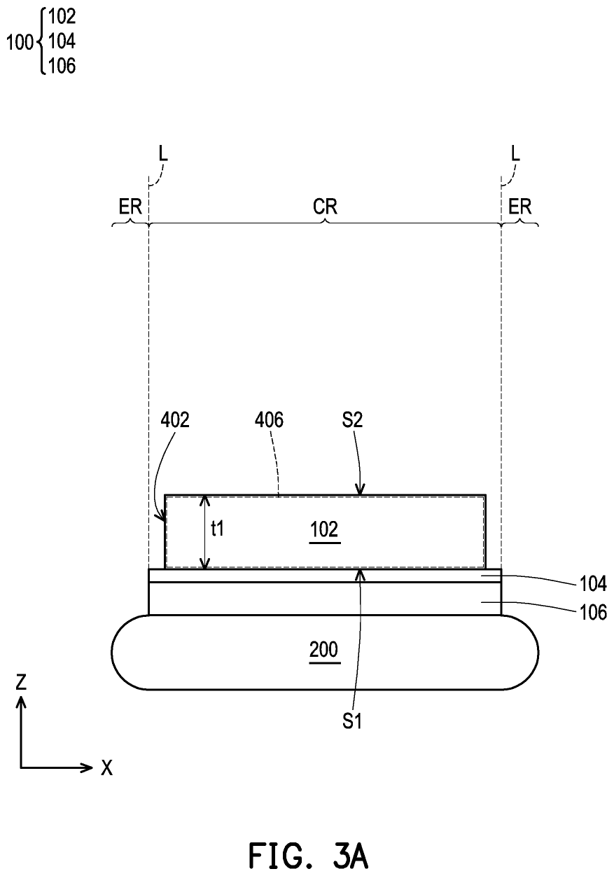

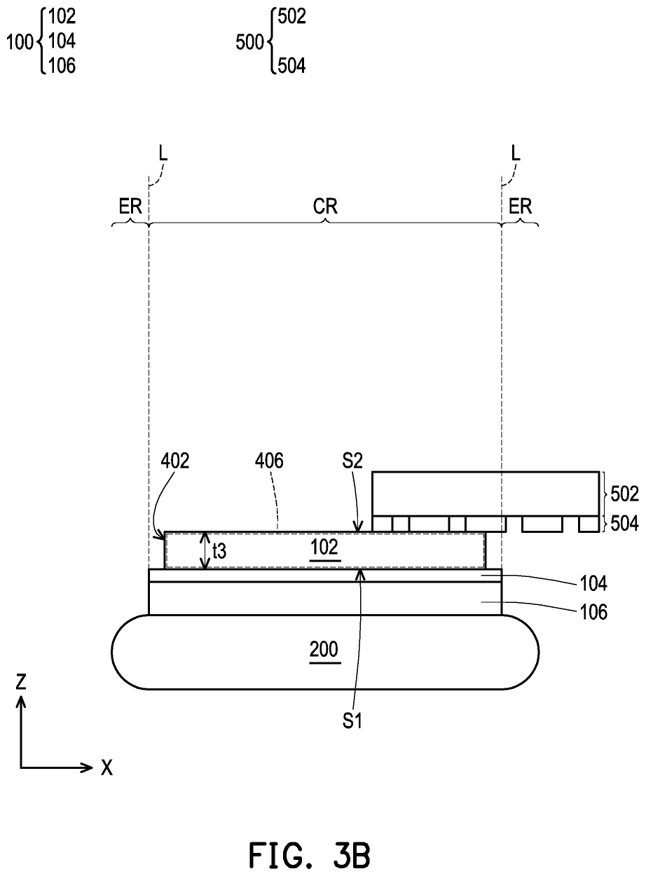

In the trimming method of the stacked wafer structure shown in FIG. 1A to FIG. 1E, during the grinding process, the flange pattern 404 is present over the second wafer 200 without being ground. However, the disclosure is not limited thereto. In some alternative embodiments, before the grinding process, the flange pattern 404 is removed. Hereinafter, other embodiments will be described with reference to FIG. 3A to FIG. 3B.

FIG. 3A through FIG. 3B illustrates schematic cross-sectional views of various stages of a trimming method of a stacked wafer structure, in accordance with some alternative embodiments of the present disclosure. The elements similar to or substantially the same as the elements described previously will use the same reference numbers, and certain details or descriptions (e.g., the materials, formation processes, positioning configurations, etc.) of the same or similar elements would not be repeated herein, and differences between the embodiments with reference to FIGS. 3A-3B and the embodiments described previously will be described below.

Referring to FIG. 3A, a structure same as the structure of FIG. 1C is provided. Details or descriptions (e.g., the materials, formation processes, positioning configurations, etc.) of the semiconductor substrate 102 (including the flange pattern 404 and the body pattern 406), the etch stop layer 104, the device layer 106, and the second wafer 200 have been described in conjunction with FIGS. 1A-1C above, and will not be iterated herein again. Accordingly, for details or descriptions of the semiconductor substrate 102 (including the flange pattern 404 and the body pattern 406), the etch stop layer 104, the device layer 106, and the second wafer 200 not iterated herein, please refer to the aforesaid embodiments.

Continued on FIG. 3A, the flange pattern 404 is removed. As shown in FIG. 3A, after the flange pattern 404 is removed, a portion of the etch stop layer 104 is exposed. In some embodiments, the flange pattern 404 is removed by performing a bevel etching process. In some embodiments, the bevel etching process includes a wet bevel etching process, a plasma bevel process, or laser heating.

Referring to FIG. 3B, a grinding process is performed on the semiconductor substrate 102 of the first wafer 100 to thin down the semiconductor substrate 102. That is, the grinding process is performed to reduce the thickness of the semiconductor substrate 102. In detail, as shown in FIG. 3A and FIG. 3B, since the flange pattern 404 is removed, during the grinding process, the body pattern 406 is thinned until the remained portion of the body pattern 406 has a desired thickness t3. In some embodiments, the grinding process may comprise bringing a grinding wheel 500 including a base 502 and a plurality of abrasive elements 504 into contact with the second surface S2 of the body pattern 406 (or the semiconductor substrate 102), as shown in FIG. 3B. Details or descriptions of the grinding process and the thickness t3 been described in conjunction with FIG. 1D above, and thus for details or descriptions of the grinding wheel 500, the base 502, the abrasive elements 504 and the thickness t3 not iterated herein, please refer to the aforesaid embodiments. Further, referring to both FIG. 3B and FIG. 1E, after the grinding process is performed, the semiconductor substrate 102 (including the body pattern 406) and the etch stop layer 104 are removed, such that the trimming method of the stacked wafer structure is substantially completed.

In accordance with an embodiment, a trimming method includes the following steps. A first wafer including a substrate and a device layer over a first side of the substrate is provided. The first wafer is bonded to a second wafer with the first side of the substrate facing toward the second wafer. An edge trimming process is performed to remove a trimmed portion of the substrate from a second side opposite to the first side vertically downward toward the first side in a first direction along a perimeter of the substrate, wherein the edge trimming process results in the substrate having a flange pattern laterally protruding from the device layer and laterally surrounding an untrimmed portion of the substrate along a second direction perpendicular to the first direction. A grinding process is performed on the untrimmed portion of the substrate from the second side to thin the untrimmed portion of the substrate to a reduced thickness in the first direction, wherein the grinding process results in the reduced thickness being greater than a thickness of the flange pattern.

In accordance with an embodiment, a trimming method includes the following steps. A first wafer including a semiconductor substrate and a device layer is provided, wherein the semiconductor substrate has a bonding region and a non-bonding region surrounding the bonding region, the semiconductor substrate has a first surface and a second surface opposite to the first surface in the bonding region, and the device layer is disposed over the first surface of the semiconductor substrate, wherein the bonding region of the semiconductor substrate has a first thickness. The first wafer is bonded to a second wafer with the device layer being between the second wafer and the semiconductor substrate. The non-bonding region of the semiconductor substrate is trimmed from the second surface of the semiconductor substrate downward toward the first surface along a perimeter of the substrate to a trimming depth and form a trimmed edge, wherein the trimming depth is less than the first thickness. The bonding region of the semiconductor substrate is thinned from the second surface of the semiconductor substrate to reduce the first thickness to a second thickness, wherein a thickness difference between the first thickness and the second thickness is less than the trimming depth.

In accordance with an embodiment, a trimming method includes the following steps. A first wafer including a semiconductor substrate and a device layer is provided, wherein the semiconductor substrate has a central region and an edge region surrounding the central region, the semiconductor substrate has a first surface and a second surface opposite to the first surface in the central region, and the device layer is disposed over the first surface of the semiconductor substrate along a thickness direction. The first wafer is bonded to a second wafer with the first surface being nearer to the second wafer than the second surface along the thickness direction. An edge trimming process is performed on the semiconductor substrate from the second surface toward the first surface along the thickness direction to form a ring-shaped opening in the central region and the edge region. A thinning process is performed on the second surface of the semiconductor substrate to allow a bottom surface of the ring-shaped opening is lower than the second surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A trimming method, comprising:
providing a first wafer including a substrate and a device layer over a first side of the substrate;
bonding the first wafer to a second wafer with the first side of the substrate facing toward the second wafer;
performing an edge trimming process to remove a trimmed portion of the substrate from a second side opposite to the first side vertically downward toward the first side in a first direction along a perimeter of the substrate, wherein the edge trimming process results in the substrate having a flange pattern laterally protruding from the device layer and laterally surrounding an untrimmed portion of the substrate along a second direction perpendicular to the first direction; and
performing a grinding process on the untrimmed portion of the substrate from the second side to thin the untrimmed portion of the substrate to a reduced thickness in the first direction, wherein the grinding process results in the reduced thickness being greater than a thickness of the flange pattern.

2. The trimming method according to claim 1, wherein along the first direction, a vertical projection of the flange pattern onto the second wafer is within a span of a vertical projection of the device layer onto the second wafer.

3. The trimming method according to claim 1, wherein the first wafer further comprises an etch stop layer over the first side of the substrate and between the substrate and the device layer.

4. The trimming method according to claim 3, wherein the flange pattern is in contact with the etch stop layer.

5. The trimming method according to claim 3, after performing the grinding process, further comprising:
removing the substrate to expose the etch stop layer; and
removing the etch stop layer to expose the device layer.

6. The trimming method according to claim 1, wherein a thickness of the trimmed portion of the substrate is less than a thickness of the untrimmed portion of the substrate along the first direction.

7. The trimming method according to claim 1, wherein a thickness difference between the reduced thickness of the untrimmed portion and the thickness of the flange pattern is greater than 1 μm.

8. The trimming method according to claim 1, wherein the flange pattern is resulted by performing the edge trimming process followed by a bevel etching process.

9. A trimming method, comprising:
providing a first wafer including a semiconductor substrate and a device layer, wherein the semiconductor substrate has a bonding region and a non-bonding region surrounding the bonding region, the semiconductor substrate has a first surface and a second surface opposite to the first surface in the bonding region, and the device layer is disposed over the first surface of the semiconductor substrate, wherein the bonding region of the semiconductor substrate has a first thickness;
bonding the first wafer to a second wafer with the device layer being between the second wafer and the semiconductor substrate;
trimming the non-bonding region of the semiconductor substrate from the second surface of the semiconductor substrate downward toward the first surface along a perimeter of the substrate to a trimming depth and form a trimmed edge, wherein the trimming depth is less than the first thickness; and
thinning the bonding region of the semiconductor substrate from the second surface of the semiconductor substrate to reduce the first thickness to a second thickness, wherein a thickness difference between the first thickness and the second thickness is less than the trimming depth.

10. The trimming method according to claim 9, wherein the trimmed edge is located within the bonding region of the semiconductor substrate.

11. The trimming method according to claim 9, wherein the first wafer further comprises an etch stop layer in the bonding region of the semiconductor substrate and between the semiconductor substrate and the device layer.

12. The trimming method according to claim 11, after the step of thinning the bonding region of the semiconductor substrate, further comprising:
removing the semiconductor substrate by a first etching process; and
removing the etch stop layer by a second etching process, wherein during the first etching process, the semiconductor substrate and the etch stop layer comprise materials with different etching selectivities.

13. The trimming method according to claim 9, wherein the non-bonding region of the semiconductor substrate includes a first bevel region extending between the first surface and an outermost edge of the semiconductor substrate, and a second bevel region extending between the outermost edge and the second surface.

14. The trimming method according to claim 13, wherein after the non-bonding region of the semiconductor substrate is trimmed, the second bevel region is removed while the first bevel region remains.

15. The trimming method according to claim 14, after the non-bonding region of the semiconductor substrate is trimmed and before the bonding region of the semiconductor substrate is thinned, further comprising performing a bevel etching process to remove the remained first bevel region.

16. A trimming method, comprising:
providing a first wafer including a semiconductor substrate and a device layer, wherein the semiconductor substrate has a central region and an edge region surrounding the central region, the semiconductor substrate has a first surface and a second surface opposite to the first surface in the central region, and the device layer is disposed over the first surface of the semiconductor substrate along a thickness direction;
bonding the first wafer to a second wafer with the first surface being nearer to the second wafer than the second surface along the thickness direction;
performing an edge trimming process on the semiconductor substrate from the second surface toward the first surface along the thickness direction to form a ring-shaped opening in the central region and the edge region; and
performing a thinning process on the second surface of the semiconductor substrate to allow a bottom surface of the ring-shaped opening is lower than the second surface.

17. The trimming method according to claim 16, wherein during the thinning process, the semiconductor substrate has a stepped profile.

18. The trimming method according to claim 16, wherein the thinning process is a grinding process.

19. The trimming method according to claim 16, wherein the first wafer further comprises an etch stop layer in the central region of the semiconductor substrate and between the semiconductor substrate and the device layer.

20. The trimming method according to claim 16, wherein the ring-shaped opening is formed by performing the edge trimming process followed by a bevel etching process.
